(19) United States
(12) Patent Application Publication
(10) Pub. No.: US 2024/0332901 A1
(43) Pub. Date: Oct. 3, 2024

(54) SURFACE-EMITTING SEMICONDUCTOR LASER AND METHOD FOR PRODUCING A SURFACE-EMITTING SEMICONDUCTOR LASER

(71) Applicant: AMS-OSRAM International GmbH, Regensburg (DE)

(72) Inventors: Hubert HALBRITTER, Dietfurt-Toeging (DE); Lutz HOEPPEL, Alteglofsheim (DE); Sven GERHARD, Alteglofsheim (DE)

(73) Assignee: AMS-OSRAM International GmbH, Regensburg (DE)

(21) Appl. No.: 18/576,609

(22) PCT Filed: Jun. 29, 2022
(86) PCT No.: PCT/EP2022/067961

§ 371 Date: Jan. 4, 2024

(30) Foreign Application Priority Data
Jul. 7, 2021 (DE) 10 2021 117 534.8

(51) Int. Cl. H01S 5/183; H01S 5/32; H01S 5/323

(52) U.S. Cl. CPC H01S 5/18311; H01S 5/18347; H01S 5/18361; H01S 5/3211; H01S 5/32341

(57) ABSTRACT

The invention relates to a surface-emitting semiconductor laser, including a first semiconductor layer of a first conductivity type, the first semiconductor layer being structured forming a mesa, an active zone for generating electromagnetic radiation and a second semiconductor layer of a second conductivity type. The first semiconductor layer, the active zone and the second semiconductor layer are arranged on top of one another forming a semiconductor layer stack. The surface-emitting semiconductor laser further comprises a sheath layer which adjoins a lateral wall of the mesa.

### CROSS-REFERENCE TO RELATED APPLICATIONS

The present application is a national stage entry from International Application No. PCT/EP2022/067961, filed on Jun. 29, 2022, published as International Publication No. WO 2023/280662 A2 on Jan. 12, 2023, and claims priority to German Patent Application No. 10 2021 117 534.8, filed Jul. 7, 2021, the disclosures of all of which are hereby incorpo-rated by reference in their entireties.

### BACKGROUND

Surface-emitting semiconductor lasers, i.e., laser devices in which the generated laser light is emitted perpendicularly to a surface of a semiconductor layer array, may be used, for example, in 3D sensor systems, e.g., for face recognition or distance measurement in autonomous driving. Furthermore, they may be used in numerous consumer products, for example display devices.

In general, efforts are being made to improve such surface-emitting lasers.

It is an object of the present invention to provide an improved surface-emitting semiconductor laser and an improved method.

According to embodiments, the object is achieved by the subject matter of the independent claims. Advantageous further developments are defined in the dependent claims.

### SUMMARY

A surface-emitting semiconductor laser comprises a first semiconductor layer of a first conductivity type, the first semiconductor layer being patterned to form a mesa, an active region for generating electromagnetic radiation, and a second semiconductor layer of a second conductivity type. The first semiconductor layer, the active region, and the second semiconductor layer are stacked on top of each other to form a semiconductor layer stack. The surface-emitting semiconductor laser further comprises a cladding layer adjacent to a sidewall of the mesa.

For example, the first and second semiconductor layers may include AlₓGa_{y}In_{1-x-y}N with 0 x≤1, 0<y≤1. In particular, the first and second semiconductor layers may be GaN layers.

For example, a material of the cladding layer may be selected such that a refractive index of the material of the cladding layer is smaller than the refractive index of the first semiconductor layer. In this way, an integrated waveguide is provided.

A material of the cladding layer may include AlN.

According to embodiments, a diameter of the mesa may be smaller than 10 μm. In this way, only the fundamental mode or only a few higher order modes may be formed. As a result, optical losses may be reduced. According to embodiments, the diameter of the mesa may be precisely dimensioned such that only one fundamental mode is formed. In this way, tailored and reproducible radiation patterns may be generated.

According to embodiments, the entire semiconductor layer stack may be patterned into a mesa.

For example, a material of the cladding layer may be selected such that an absorption coefficient of the material of the cladding layer is smaller than the absorption coefficient of the first semiconductor layer. In this way, losses may be further reduced.

According to embodiments, the surface-emitting semiconductor laser may further comprise first and second resonator mirrors. Accordingly, a vertical resonator may be formed. The first resonator mirror may be disposed on a side of the first semiconductor layer, and the second resonator mirror may be disposed on a side of the second semiconductor layer. According to embodiments, the first and second resonator mirrors may be insulating. According to further embodiments, one of the two resonator mirrors may be insulating, and the other one of the two resonator mirrors is electrically conductive.

For example, the semiconductor layer stack is disposed over a growth substrate for growing the first and second semiconductor layers.

According to further embodiments, the semiconductor layer stack may also be disposed over a metallic substrate.

The surface-emitting semiconductor laser may further comprise an aperture for guiding a current, wherein an opening diameter of the aperture is smaller than a diameter of the mesa.

For example, the mesa has a hexagonal shape in a horizontal plane.

According to embodiments, a sidewall of the mesa corresponds to a crystal face of the material of the first semiconductor layer. In this way, a particularly smooth and low-defect sidewall may be realized, further reducing losses.

According to embodiments, a method of manufacturing a surface-emitting semiconductor laser comprises forming a first semiconductor layer of a first conductivity type, forming an active region for generating electromagnetic radiation, and forming a second semiconductor layer of a second conductivity type. In this method, the first semiconductor layer, the active region, and the second semiconductor layer are stacked on top of each other to form a semiconductor layer stack. The method further comprises patterning the first semiconductor layer to form a mesa, and forming a cladding layer adjacent to a sidewall of the mesa.

For example, the cladding layer may be applied by sputtering over the sidewall of the mesa. The process may further include a temperature treatment step at a temperature of at least 800° C.

For example, patterning the first semiconductor layer may include a wet etch process.

An optoelectronic semiconductor device includes the semiconductor surface-emitting laser as described above. The optoelectronic semiconductor device may, for example, be selected from an illumination device, a projection device, or a display device.

### BRIEF DESCRIPTION OF THE DRAWINGS

The accompanying drawings serve to provide an understanding of exemplary embodiments of the invention. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of a surface-emitting semiconductor laser according to embodiments.

FIG. 1B shows a schematic diagram of the refractive index of the semiconductor materials used according to embodiments.

FIG. 1C shows a cross-sectional view of a surface-emitting semiconductor laser according to further embodiments.

FIGS. 2A to 2C show schematic cross-sectional views of further surface-emitting semiconductor lasers according to embodiments.

FIG. 3A shows schematic horizontal cross-sectional views of a mesa according to embodiments.

FIG. 3B shows a schematic vertical cross-sectional view of components of the surface-emitting semiconductor laser according to embodiments.

FIG. 4A illustrates steps for manufacturing a surface-emitting semiconductor laser according to embodiments.

FIG. 4B shows a workpiece in the course of performing a method according to embodiments.

FIG. 4C shows the workpiece after further processing steps have been carried out.

FIG. 5 outlines a method according to embodiments.

FIG. 6 shows an optoelectronic semiconductor device according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since other exemplary embodiments may also exist and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may basically include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material, for example a GaAs substrate, a GaN-substrate, or an Si substrate, or of an insulating material, for example sapphire.

Depending on the intended use, the semiconductor may be based on a direct or an indirect semiconductor material. Examples of semiconductor materials particularly suitable for generating electromagnetic radiation include, without limitation, nitride semiconductor compounds by means of which, for example, ultraviolet, blue or longer-wave light may be generated, such as GaN, InGaN, AlN, AlGaN, AlGaInN, AlGaInBN; phosphide semiconductor compounds by means of which, for example, green or longer-wave light may be generated, such as GaAsP, AlGaInP, GaP, AlGaP; and other semiconductor materials such as GaAs, AlGaAs, InGaAs, AlInGaAs, SiC, ZnSe, ZnO, Ga₂O₃, diamond, hexagonal BN; and combinations of the materials mentioned. The stoichiometric ratio of the compound semiconductor materials may vary. Other examples of semiconductor materials may include silicon, silicon germanium, and germanium.

The term “substrate” generally includes insulating, conductive, or semiconductor substrates.

The terms “lateral” and “horizontal”, as used in the present description, are intended to describe an orientation or alignment which extends essentially parallel to a first surface of a substrate or a semiconductor body. This may be the surface of a wafer or a chip (die), for example.

The horizontal direction may, for example, be in a plane perpendicular to a direction of growth when layers are grown.

The term “vertical”, as used in this description, is intended to describe an orientation which is essentially perpendicular to the first surface of a substrate or a semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

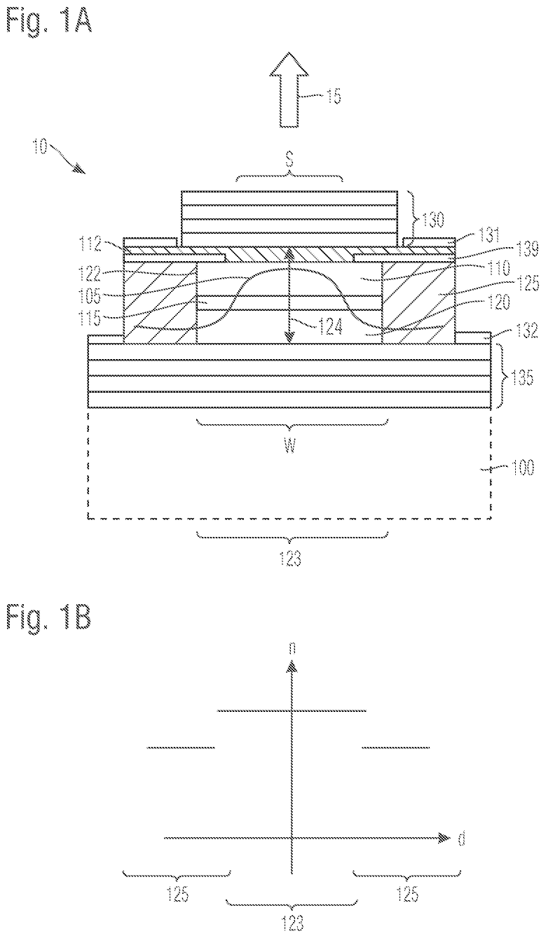

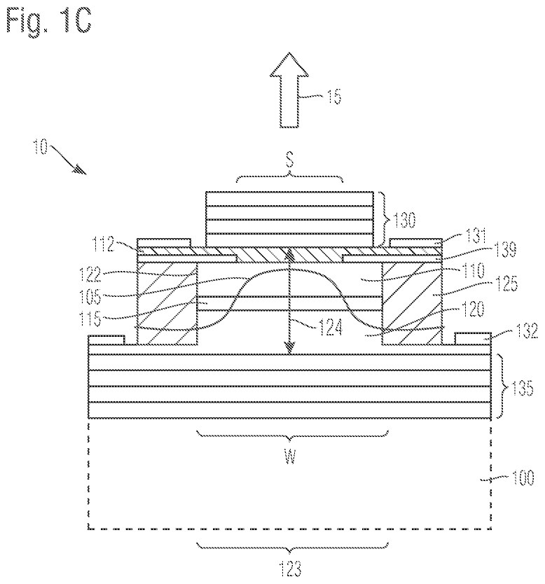

FIG. 1A shows a schematic cross-sectional view of a surface-emitting semiconductor laser 10 according to embodiments.

The surface-emitting semiconductor laser shown in FIG. 1A comprises a first semiconductor layer 110 of a first conductivity type, for example p-type, an active region 115 for generating electromagnetic radiation, and a second semiconductor layer 120 of a second conductivity type, for example n-type. The first semiconductor layer 110, the active region 115, and the second semiconductor layer 120 are stacked on top of each other to form a semiconductor layer stack 121. The first semiconductor layer 110 is patterned to form a mesa 123. The surface-emitting semiconductor laser 10 further includes a cladding layer 125 adjacent to a sidewall 122 of the mesa 123.

The active zone 115 may, for example, comprise a pn junction, a double heterostructure, a single quantum well structure (SQW, single quantum well), or a multiple quantum well structure (MQW, multi quantum well) for generating radiation.

The term “quantum well structure” does not imply any particular meaning here with regard to the dimensionality of the quantization. Therefore, it includes, among other things, quantum wells, quantum wires and quantum dots as well as any combination of these structures.

For example, the first and second semiconductor layers comprise GaN. For example, the first and second semiconductor layers may be of the composition AlₓGa_{y}In_{1-x-y}N with 0≤x<1, 0<y≤1. In this way, it is possible to emit laser radiation having small wavelengths.

For example, the cladding layer 125 has a refractive index that is smaller than the refractive index of the first and second semiconductor layers. For example, the refractive index of GaN is 2.46. Accordingly, when GaN semiconductor layers are used according to embodiments, the refractive index of the cladding layer 125 is selected to be less than 2.46. For example, the cladding layer may comprise AlN having a refractive index of about 2.2. In this way, it is possible to limit losses that could be problematic in the GaN material system. As a consequence, the photon density within the mesa is in-creased. In particular, due to the presence of the cladding layer 125, a waveguide effect is achieved that leads to an improved photon density even below the laser threshold. In this way, it is possible to reduce the laser threshold.

For example, a diameter w of the mesa 123 is dimensioned such that, typically, only the fundamental mode, for example a Gaussian mode, is formed. According to further embodiments, it is possible that a few higher order modes are formed. In this way, the photons may concentrate even more within the mesa. If the diameter w of the mesa 123 is precisely defined so that only the fundamental mode may be developed, a defined beam waist is generated. In this way, tailored and reproducible beam characteristics are made possible. For example, the diameter w of the mesa 123 may be smaller than 10 μm or smaller than 5 μm. According to further embodiments, the diameter w of the mesa 123 may even be smaller than 2 μm or smaller than 1 μm.

FIG. 1A further shows the radiation intensity 105 within the mesa 123. When only a fundamental mode is formed, a maxi-mum photon concentration occurs in the central region of the mesa 123, which may help to avoid losses within the surface-emitting semiconductor laser. In particular, spatial expansion of the modes is reduced. As a result, optical losses are reduced. Optical losses due to mode broadening could cause problems especially in surface-emitting semiconductor lasers with resonator mirrors of high mirror reflectivity.

For example, an absorption coefficient α of the cladding layer 125 may be smaller than the absorption coefficient of the first and second semiconductor layers. In this way, losses in the surface-emitting semiconductor laser may be further reduced.

According to embodiments, the surface-emitting semiconductor laser may further comprise an aperture 139 for guiding a current. The aperture 139 may be implemented, for example, by a SiO layer or oxidized insulating semiconductor material. In this case, an aperture diameter s of the aperture 139 may be smaller than a diameter w of the mesa 123. In this way, a particularly favorable overlap of optical mode and charge carrier density is achieved. Furthermore, charge carriers—due to their reduced drift—may be effectively kept away from the mesa edge. This avoids undesirable recombinations, which bring about losses.

By selecting a cladding layer material of a low absorption coefficient, absorption losses of lateral evanescent fields in the first and second semiconductor layers may be reduced.

Furthermore, it is possible to improve lateral heat dissipation of the device by using a material of the cladding layer 125 having a higher thermal conductivity coefficient than the thermal conductivity coefficient of the semiconductor layers.

The surface-emitting semiconductor laser 10 may, for example, be formed as a vertical cavity surface-emitting semiconductor laser (VCSEL). For example, it has a first resonator mirror 130 and a second resonator mirror 135. In this way, an optical resonator 124 is formed between the first resonator mirror 130 and the second resonator mirror 135.

According to further embodiments, the surface-emitting semiconductor laser 10 may also be a PCSEL (“photonic crystal surface-emitting laser”). In this case, the surface-emitting semiconductor laser 10 has an ordered photonic structure.

If the surface-emitting semiconductor laser 10 is implemented as a VCSEL, the first and second resonator mirrors 130, 135 may be Bragg mirrors, for example.

A Bragg mirror comprises a sequence of very thin dielectric or semiconductor layers, each having a different refractive index. For example, the layers may have alternating high refractive indices and low refractive indices. For example, the layer thickness may be λ/4, where λ indicates the wave-length of the light to be reflected in the respective medium.

The layer as seen from the incident light may have a greater layer thickness, for example 3λ/4. Due to the small layer thickness and the difference in the respective refractive indices, the Bragg mirror provides high reflectivity. A Bragg mirror may comprise 2 to 50 layers, for example. A typical layer thickness of the individual layers may be about 30 to 90 nm, for example about 50 nm. The layer stack may further include one or two or more layers thicker than about 180 nm, for example thicker than 200 nm.

The first resonator mirror 130 may, for example, comprise semiconductor or dielectric layers. The second resonator mirror 135 may, for example, comprise semiconductor layers that may be epitaxially grown. For example, the layers of the second resonator mirror 135 and the semiconductor layer stack 121 may be epitaxially formed over a growth substrate. For example, the substrate 100 shown in FIG. 1A may be a growth substrate or a substrate other than a growth substrate.

The first semiconductor layer 110 may, for example, be electrically connectable via a first contact element 131. The first contact element 131 may, for example, be connected to the first semiconductor layer 110 via a conductive layer 112, for example an ITO (“indium tin oxide”) layer. In FIG. 1A, the second contact element 132 is electrically connected to the second semiconductor layer 120 via the second resonator mirror 135. According to further embodiments, alternative connection options may also be implemented for the first semiconductor layer 110 and for the second semiconductor layer 120.

Generated laser radiation 15 may be output, for example, via the first main surface 111 of the first semiconductor layer 110.

FIG. 1B schematically shows the course of the refractive index N within the mesa 123 and the cladding layer 125. Due to the fact that the refractive index of the material of the cladding layer 125 is smaller than the refractive index of the semiconductor layer or within the mesa 123, optical guidance of the generated electromagnetic waves occurs.

FIG. 1C shows a schematic cross-sectional view of a surface-emitting semiconductor laser according to further embodiments. The individual components of the depicted surface-emitting semiconductor laser 10 are substantially the same as those described with reference to FIG. 1A. However, in a departure from the semiconductor laser of FIG. 1A, the second resonator mirror is in this case electrically insulating and includes dielectric layers. Accordingly, the second semiconductor layer 120 may be electrically connectable via a second contact element 132 directly adjacent to the second semiconductor layer 120. For example, greater differences in refractive indices may be induced by using dielectric layers, resulting in greater reflectivity.

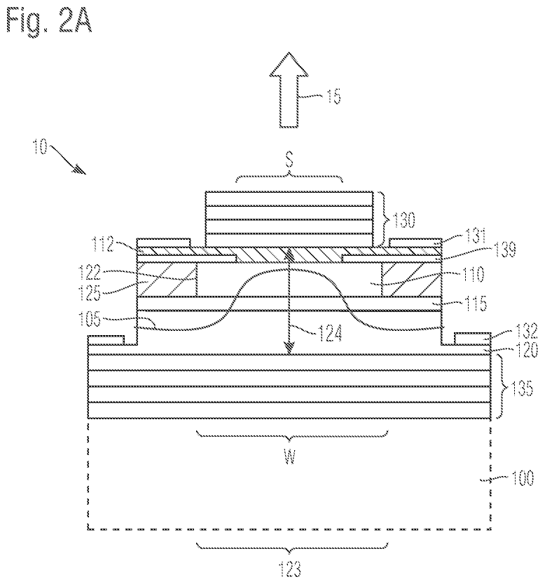

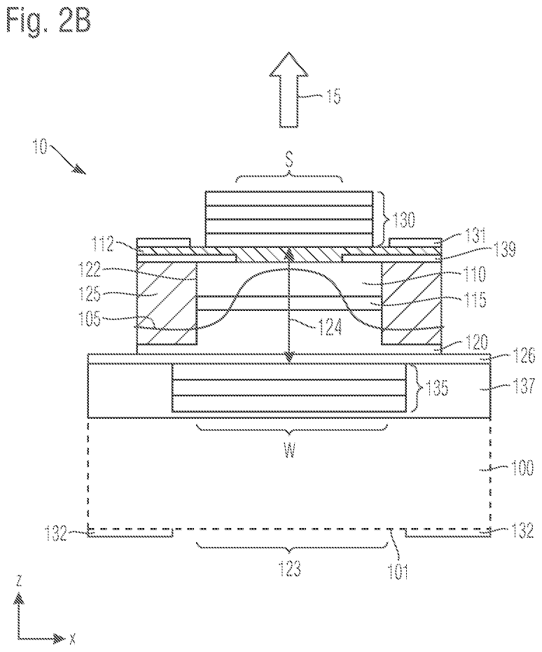

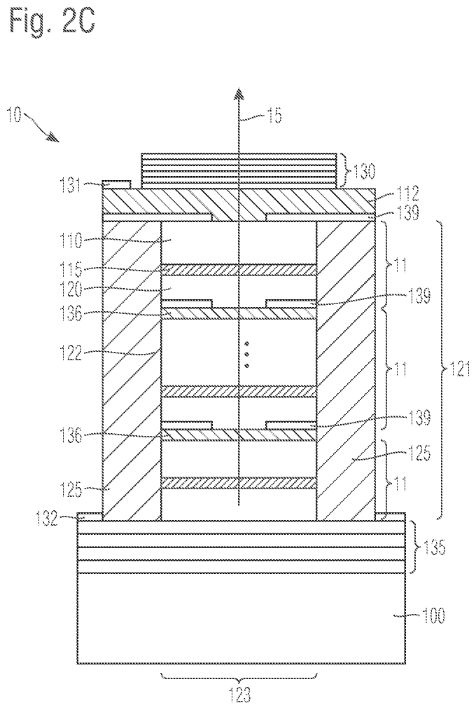

FIG. 2A shows a schematic view of a surface-emitting semiconductor laser 10 according to further embodiments. The components shown in FIG. 2A are substantially the same as those discussed with reference to FIGS. 1A and 1C. In a departure therefrom, only the first semiconductor layer 110 is adjacent to the cladding layer 125. Accordingly, it is possible that only a portion of the semiconductor layer stack 121 is configured as a waveguide. The lower part of the semiconductor layer stack 121 may also be patterned into a mesa, but in a lower region, the cladding layer 125 is not adjacent to the second semiconductor layer 120. Thus, it is possible that no waveguide is formed in the lower portion.

As shown in FIG. 2A, the cladding layer 125 may be adjacent to a sidewall of the first semiconductor layer 110. However, the cladding layer 125 is not adjacent to a sidewall of the active zone 115. According to further embodiments, the cladding layer may also be adjacent to a sidewall of the active zone 115. Moreover, it may also be adjacent to a portion of the second semiconductor layer 120.

FIG. 2B shows a schematic cross-sectional view of a surface-emitting semiconductor laser according to further embodiments. Components shown in FIG. 2B substantially correspond to components described with reference to FIGS. 1A to 1C and 2A. However, in a departure therefrom, the substrate 100 is not the growth substrate for growing the semiconductor layer stack 121. For example, according to embodiments shown in FIG. 2B, the second resonator mirror 135 may include dielectric layers. The second resonator mirror 135 may be embedded in a carrier 137 having, for example, good thermal coupling. For example, the carrier 137 may also have high reflectivity. For example, the carrier 137 may include or be composed of a metal, such as gold, silver, or aluminum. In this way, generated electromagnetic radiation may be reflected back into the semiconductor layer stack 121 to a high degree. Furthermore, good thermal coupling may be achieved. The second contact element 132 may be arranged, for example, on a second main surface 101 of the substrate 100. According to further embodiments, the second contact element 132 may also be adjacent to a free surface of the interconnection layer 126. The interconnection layer 126 may, for example, be a transparent conductive oxide, such as ITO, or may be a semiconductor material. According to further embodiments, the interconnection layer 126 may also be omit-ted.

As further illustrated in FIG. 2B, the cladding layer 125 may be adjacent to the first semiconductor layer 110, the active zone 115, and a portion of the second semiconductor layer 120. However, according to further embodiments, the cladding layer 125 may be implemented other ways than those previously described.

In order to manufacture the surface-emitting semiconductor laser shown in FIG. 2B, the semiconductor layers are grown on a growth substrate to form the semiconductor layer stack 121, then peeled off and deposited or transferred onto the carrier 137 in or on which the second resonator mirror 135 is formed. For example, the carrier 137 may be deposited over a substrate 100.

FIG. 2C shows a surface-emitting semiconductor laser 10 according to further embodiments. The components of the surface-emitting semiconductor laser shown in FIG. 2C are substantially the same as those described with reference to FIG. 1A. However, in a departure therefrom, the semiconductor layer stack 121 comprises a multiplicity of layers to form a plurality of semiconductor laser elements 11, which are stacked on top of each other in the vertical direction and which are connected to each other via tunnel junctions 136.

A tunnel junction comprises a p++-doped layer, an n++-doped layer, and optionally an intermediate layer, which are arranged in the reverse direction and constitute a tunnel di-ode.

For example, an aperture 139 may also be provided in each case to guide the current. The diameter of the aperture 139 may vary. The semiconductor layer stack 121 is patterned to form a mesa 123. The width w of the mesa 123 may vary within the semiconductor layer stack. A cladding layer 125 is adjacent to a sidewall 122 of the mesa 123. According to embodiments, the cladding layer may be adjacent to only a portion of the semiconductor layer stack 121.

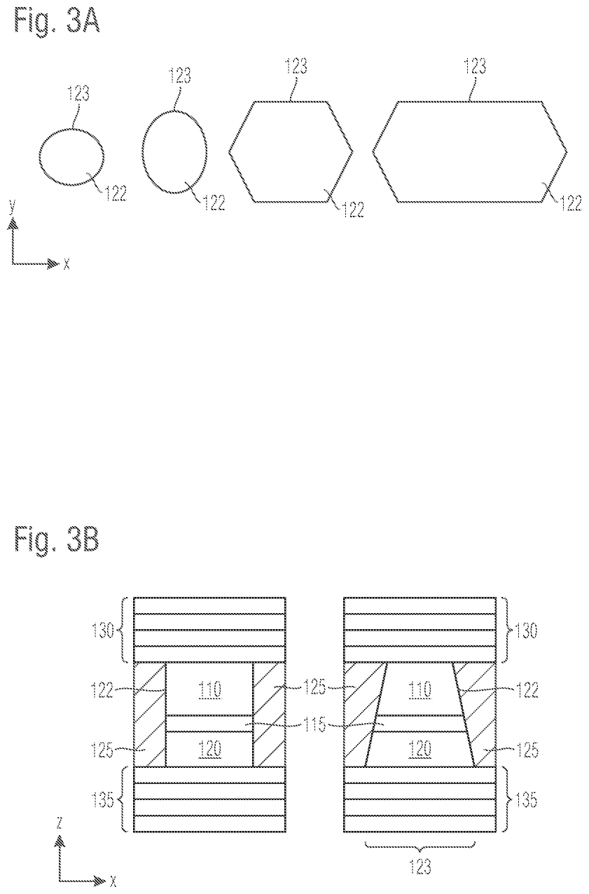

As shown in FIG. 3A, the mesa 123 may be formed to have a variety of shapes. For example, the mesa may be circular or elliptical in plan view, i.e., in the horizontal x-y plane. For example, in an elliptical configuration of the mesa 123, the polarization of the generated electromagnetic radiation may be adjusted as well. According to further embodiments, the mesa may also have the shape of a polygon, for example a hexagon. According to further embodiments, the mesa may also have the shape of an elongated hexagon, thereby allowing for the polarization of the generated electromagnetic radiation to be adjusted. According to embodiments, the sidewalls 122 of the hexagonal structures may correspond to the crystallographic m-plane. This means that the sidewall 122 of the mesa 123 may extend along crystal axes of the semiconductor material. In this way, a very smooth mesa edge may be created, reducing scattering losses within the semiconductor layer stack.

FIG. 3B shows a schematic vertical cross-sectional view of portions of the surface-emitting semiconductor laser. As shown in the left portion of FIG. 3B, the sidewall 122 of the mesa 123 may extend along the Z direction. According to further embodiments, shown for example in the right part of FIG. 3B, the sidewall 122 of the mesa 123 may also extend obliquely, i.e., along a direction that intersects but is not parallel to the vertical or z-axis. In the x-y plane, the mesa may have any shape, for example one that has been described with reference to FIG. 3A.

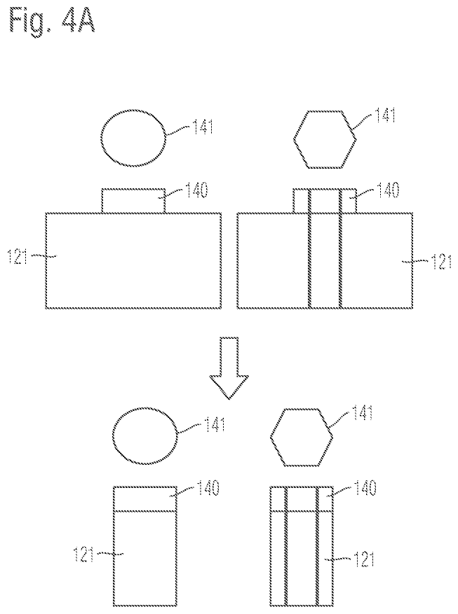

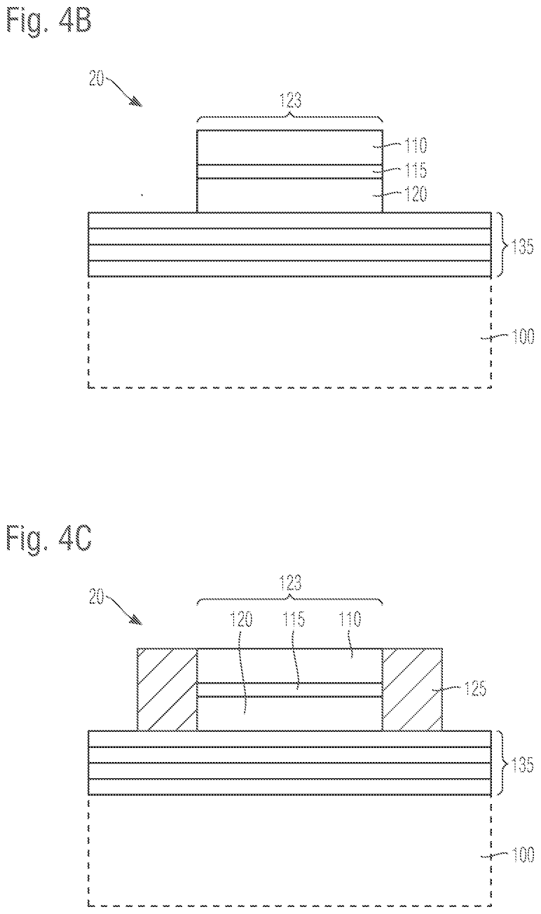

In order to form the mesa, for example, an etch mask 140 may be formed over the semiconductor layer stack 121. For example, as shown in the left-hand portion of FIG. 4A, the etch mask 140 may have a circular cross-section 141. According to further embodiments, as shown in the right-hand portion of FIG. 4A, the etch mask may also have a hexagonal cross-section 141. Then a wet etching process is carried out, for example in basic chemistry (KOH, TMAH, NH₃, NaOH). In this way, for example, crystallographic etching may be performed along the m-plane of the GaN crystal, resulting in very smooth, low-defect or defect-free flanks. Furthermore, exposure defects are compensated, since the basic symmetry properties of the crystal are prepared. By suitably modifying the conditions, it is also possible to achieve a round or elliptical etch shape. The lower part of FIG. 4A shows a correspondingly patterned semiconductor stack 121.

FIG. 4B shows a schematic cross-sectional view of a workpiece 20 after the etching process has been carried out. As may be seen, the mesa 123 is patterned according to the shape of the etch mask. For example, the flanks of the mesa may then be cleaned. Then the cladding layer 125 may be deposited on the sidewall of the mesa 123.

FIG. 4C shows a schematic cross-sectional view of the workpiece 20 comprising the deposited cladding layer 125. For example, the material of the cladding layer 125 may be formed by sputtering. To increase the crystallinity of the cladding layer 125, for example, a subsequent temperature treatment may be carried out at high temperatures, for example at temperatures up to 800° C. This may also be implemented by a laser spike temperature treatment.

Alternative or additional materials of the cladding layer may include SiO, SiN, TaO, NbO, CaF, MgF₂, AlO, undoped GaN or AlInN. According to embodiments, the material of the cladding layer is selected such that the thermal conductivity coefficient is particularly large so that existing heat may be efficiently dissipated. For example, the thermal conductivity coefficient of the cladding layer may be larger than that of the first and second semiconductor layers and the active zone.

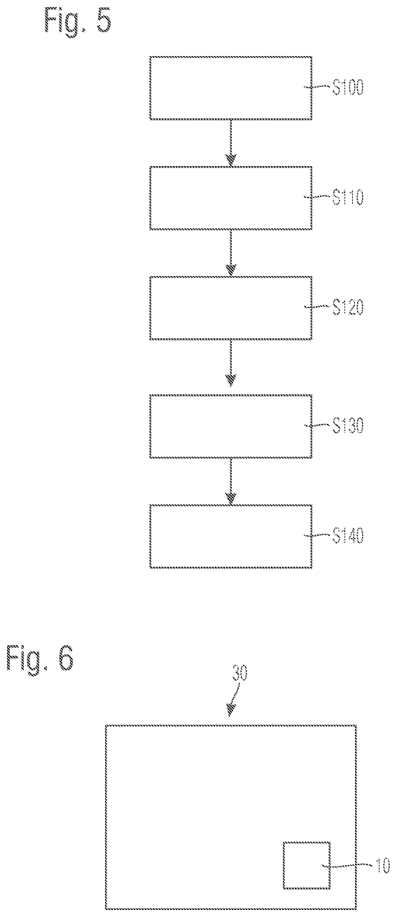

FIG. 5 outlines a method according to embodiments. A method of manufacturing a surface-emitting semiconductor laser comprises forming (S100) a first semiconductor layer of a first conductivity type, forming (S110) an active zone for generating electromagnetic radiation, and forming (S120) a second semiconductor layer of a second conductivity type, wherein the first semiconductor layer, the active zone, and the second semiconductor layer are stacked to form a semiconductor layer stack. The first semiconductor layer is patterned to form a mesa (S130). The method further comprises forming (S140) a cladding layer adjacent to a sidewall of the mesa.

According to embodiments, the concepts described herein may be further extended. For example, the individual surface-emitting semiconductor laser elements may also be implemented as an array, for example as multiple individual emitters on a chip. Further, the system may be designed such that light ex-traction also occurs through the substrate, i.e., via the second main surface 101 of the substrate.

FIG. 6 shows an optoelectronic semiconductor device 30 according to embodiments. The semiconductor optoelectronic device 30 is selected from an illumination device, a projection device, or a display device. Due to the reduced optical losses, higher efficiency and consequently higher luminance of the semiconductor optoelectronic device 30 may be obtained.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

1. A surface-emitting semiconductor laser comprising:
a first semiconductor layer of a first conductivity type,
an active zone for generating electromagnetic radiation,
a second semiconductor layer of a second conductivity type, wherein said first semiconductor layer, said active region, and said second semiconductor layer are stacked on top of each other to form a semiconductor layer stack, and
a cladding layer adjacent to a sidewall of the mesa, and
an aperture for guiding a current, wherein an opening diameter of the aperture is smaller than a diameter of the mesa,
wherein the semiconductor layer stack is patterned into a mesa and a diameter of the mesa is less than 10 μm.

2. The surface-emitting semiconductor laser according to claim 1, wherein the first and second semiconductor layers are GaN layers.

3. The surface-emitting semiconductor laser according to claim 1, wherein a material of the cladding layer is selected such that a refractive index of the material of the cladding layer is smaller than the refractive index of the first semiconductor layer.

4. The surface-emitting semiconductor laser according to claim 1, wherein a material of the cladding layer comprises AlN.

5. (canceled)

6. (canceled)

7. The surface-emitting semiconductor laser according to claim 1, wherein a material of the cladding layer is selected such that an absorption coefficient of the material of the cladding layer is smaller than the absorption coefficient of the first semiconductor layer.

8. The surface-emitting semiconductor laser according to claim 1, further comprising first and second resonator mirrors, wherein the first resonator mirror is disposed on a side of the first semiconductor layer and the second resonator mirror is disposed on a side of the second semiconductor layer, and the first and second resonator mirrors are insulating.

9. The surface-emitting semiconductor laser according to claim 1, further comprising first and second resonator mirrors, wherein the first resonator mirror is disposed on a side of the first semiconductor layer and the second resonator mirror is disposed on a side of the second semiconductor layer, and one of the two resonator mirrors is insulating and the other one of the two resonator mirrors is electrically conductive.

10. The surface-emitting semiconductor laser according to claim 1, wherein the semiconductor layer stack is disposed over a growth substrate for growing the first and second semiconductor layers.

11. The surface-emitting semiconductor laser according to claim 1, wherein the semiconductor layer stack is disposed over a metallic carrier.

12. The surface-emitting semiconductor laser according to claim 1, wherein the mesa has a hexagonal shape in a horizontal plane.

13. The surface-emitting semiconductor laser according to claim 1, wherein a sidewall of the mesa corresponds to a crystal face of the material of the first semiconductor layer.

14. A method of manufacturing a surface-emitting semiconductor laser comprising:
forming a first semiconductor layer of a first conductivity type,
forming an active zone for generating electromagnetic radiation,
forming a second semiconductor layer of a second conductivity type, wherein the first semiconductor layer, the active region, and the second semiconductor layer are stacked on top of each other to form a semiconductor layer stack,
patterning the semiconductor layer stack into a mesa having a diameter less than 10 μm,
forming a cladding layer adjacent to a sidewall of the mesa, and
forming an aperture for guiding a current, wherein an opening diameter of the aperture diaphragm is smaller than a diameter of the mesa.

15. The method according to claim 14, wherein the cladding layer is applied by sputtering over the sidewall of the mesa.

16. The method according to claim 15, further comprising a temperature treatment step at a temperature of at least 800° C.

17. The method according to claim 14, wherein patterning the first semiconductor layer comprises a wet etch process.

18. An optoelectronic semiconductor device comprising the surface-emitting semiconductor laser according to claim 1.

19. The optoelectronic semiconductor device according to claim 18, which is selected from an illumination device, a projection device, or a display device.
